(19) United States
(12) Patent Application Publication
(10) Pub. No.: US 2015/0144927 A1
(43) Pub. Date: May 28, 2015

(54) ORGANIC ELECTROLUMINESCENCE DEVICE AND MATERIAL FOR ORGANIC ELECTROLUMINESCENCE DEVICE

(71) Applicant: SAMSUNG DISPLAY CO., LTD., Yongin-City (KR)

(72) Inventors: Xiulan JIN, Yokohama (JP); Junji KIDO, Yamagata (JP); Hisahiro SASABE, Yamagata (JP); Kazuo UDAGAWA, Yamagata (JP)

(73) Assignee: NATIONAL UNIVERSITY CORPORATION YAMAGATA UNIVERSITY, Yamagata (JP)

(21) Appl. No.: 14/554,872

(22) Filed: Nov. 26, 2014

(30) Foreign Application Priority Data
Nov. 27, 2013 (JP) 2013-245383
Nov. 27, 2013 (JP) 2013-245384

(51) Int. Cl. H01L 51/00; H01L 51/50; C07F 5/02

(52) U.S. Cl. CPC H01L 51/008; C07F 5/027; H01L 51/5012; H01L 51/5088
USPC 257/40; 568/5

(57) ABSTRACT

An organic electroluminescence (EL) device includes a charge generating layer including a charge generating material or a hole injection layer including a hole injection material, the charge generating material or the hole injection material including a 1,2-closo-carborane compound represented by the following Formula 1:

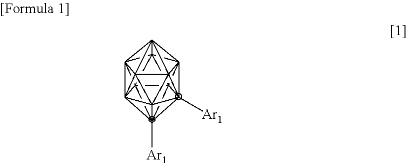

wherein each Ar₁ is independently a substituted or unsubstituted aryl group or a substituted or unsubstituted heteroaryl group.

### CROSS-REFERENCE TO RELATED APPLICATIONS

Japanese Patent Application Nos. 2013-2415384 and 2013-245383, filed on Nov. 27, 2013, in the Japanese Patent Office, and entitled: “Organic Electroluminescence Device and Material for Organic Electroluminescence Device,” are incorporated by reference herein in their entirety.

### BACKGROUND

1. Field

Embodiments relate to an organic electroluminescence device and a material for an organic electroluminescence device.

2. Description of the Related Art

In recent years, organic electroluminescence (EL) displays are one type of image displays that have been actively developed. Unlike a liquid crystal display and the like, the organic EL display is so-called a self-luminescent display which recombines holes and electrons injected from an anode and a cathode in an emission layer to thus emit lights from a light-emitting material including an organic compound of the emission layer, thereby performing display.

### SUMMARY

Embodiments are directed to an organic electroluminescence (EL) device including a charge generating layer including a charge generating material or a hole injection layer including a hole injection material, the charge generating material or the hole injection material including a 1,2-closo-carborane compound represented by the following Formula 1:

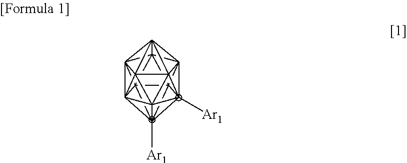

In Formula 1, each Ar₁ may independently be a substituted or unsubstituted aryl group or a substituted or unsubstituted heteroaryl group.

Each Ar₁ may independently be an aryl group substituted with an electroattracting group or a heteroaryl group substituted with an electroattracting group.

The electroattracting group may be an electroattracting group having a substituent constant (σ) greater than 0.07 in the Hammett equation.

The electroattracting group may be a halogen atom, a methyl group substituted with a halogen atom, or a cyano group.

A lowest unoccupied molecular orbital (LUMO) level of the charge generating material or a LUMO level of the hole injection material may be less than or equal to about 3.40 eV.

The organic EL device may include the charge generating layer, and the organic EL device may include at least a first emission unit and a second emission unit, the first and second emission units being stacked in series. The stacked emission units may include, in sequence, an anode, a first emission layer, the charge generating layer, a second emission layer, and a cathode.

Embodiments are also directed to an organic electroluminescence (EL) device including a charge generating layer including a charge generating material or a hole injection layer including a hole injection material, the charge generating material or the hole injection material including a 1,2-closo-carborane compound represented by the following Formula 2:

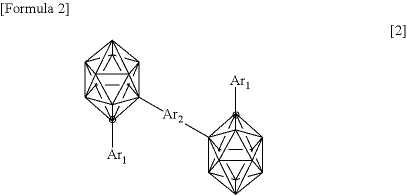

In Formula 2, each Ar₁ and Ar₂ may independently be a substituted or unsubstituted aryl group or a substituted or unsubstituted heteroaryl group.

At least one of Ar₁ or Ar₂ may be an aryl group substituted with an electroattracting group or a heteroaryl group substituted with an electroattracting group.

The electroattracting group may be an electroattracting group having a substituent constant (σ) greater than 0.07 in the Hammett equation.

The electroattracting group may be a halogen atom, a methyl group substituted with a halogen atom, or a cyano group.

A lowest unoccupied molecular orbital (LUMO) level of the charge generating material or a LUMO level of the hole injection material may be less than or equal to about 3.40 eV.

The organic EL device may include the charge generating layer, and the organic EL device may include at least a first emission unit and a second emission unit, the first and second emission units being stacked in series. The stacked emission units may include, in sequence, an anode, a first emission layer, the charge generating layer, a second emission layer, and a cathode.

Embodiments are also directed to a material for an organic electroluminescence (EL) device including a 1,2-closo-carborane compound represented by the following Formula 1:

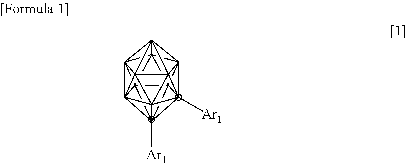

In Formula 1, each Ar₁ may independently be an aryl group substituted with an electroattracting group or a heteroaryl group substituted with an electroattracting group.

The electroattracting group may be an electroattracting group having a substituent constant (σ) greater than 0.07 in the Hammett equation.

The electroattracting group may be a halogen atom, a methyl group substituted with a halogen atom, or a cyano group.

A lowest unoccupied molecular orbital (LUMO) level of the material may be less than or equal to about 3.40 eV.

Embodiments are also directed to a material for an organic electroluminescence (EL) device including a 1,2-closo-carborane compound represented by the following Formula 2:

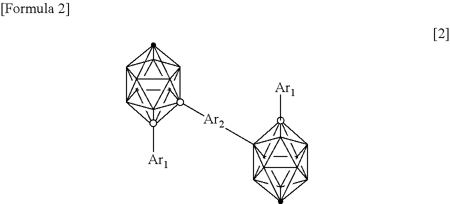

In Formula 2, each Ar₁ and Ar₂ may independently be a substituted or unsubstituted aryl group or a substituted or unsubstituted heteroaryl group.

At least one of Ar₁ or Ar₂ may be an aryl group substituted with an electroattracting group or a heteroaryl group substituted with an electroattracting group.

The electroattracting group may be an electroattracting group having a substituent constant (σ) greater than 0.07 in the Hammett equation.

The electroattracting group may be a halogen atom, a methyl group substituted with a halogen atom, or a cyano group.

A lowest unoccupied molecular orbital (LUMO) level of the material is less than or equal to about 3.40 eV.

### BRIEF DESCRIPTION OF THE DRAWINGS

Features will become apparent to those of skill in the art by describing in detail example embodiments with reference to the attached drawings in which:

FIG. 1 illustrates a schematic diagram illustrating the structure of an organic EL device according to an example embodiment;

FIG. 2 illustrates a schematic diagram illustrating the structure of an organic EL device according to an example embodiment;

FIG. 3 illustrates a schematic diagram illustrating the structure of an organic EL device according to an example embodiment; and

FIG. 4 illustrates a schematic diagram illustrating the structure of an organic EL device according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

According to an example embodiment, an organic EL device includes a charge generating layer including a charge generating material or a hole injection layer including a hole injection material. The charge generating material or the hole injection material may include a 1,2-closo-carborane compound represented by the following Formula 3.

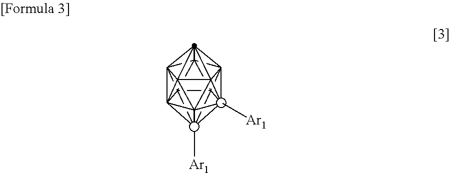

According to the present example embodiment, in Formula 3, Ar₁ is a substituted or unsubstituted aryl group or a substituted or unsubstituted heteroaryl group.

Here, as an aryl group having or not having a substituted group, an aryl group having 6 to 12 ring carbon atoms may be used, for example. As a substituted or unsubstituted heteroaryl group, a heteroaryl group having 3 to 6 ring carbon atoms may be used, for example. A material for an organic EL device having the above-described structure may form a charge generating layer or a hole injection layer, and may help realize a low voltage driving and high power efficiency of an organic EL device.

In an example embodiment, in Formula 3, Ar₁ may be an aryl group substituted with an electroattracting group or a heteroaryl group substituted with an electroattracting group. For example, by introducing the electroattracting group in Ar₁, the lowest unoccupied molecular orbital (LUMO) may be lowered, which may help realize the low voltage driving and the high power efficiency of an organic EL device. In another example embodiment, in Formula 3, Ar₁ may be a hydrogen atom or a deuterium atom.

The electroattracting group may be an electroattracting group having a substituent constant (σ) greater than 0.07 in the Hammett equation. By introducing the electroattracting group having a substituent constant (σ) greater than 0.07 in Ar₁, the LUMO may be lowered, which may help realize the low voltage driving and the high power efficiency of an organic EL device.

As the electroattracting group, a halogen atom, a cyano group, or an alkyl group substituted with a halogen atom may be used. The electroattracting group may be a fluorine atom, a trifluoromethyl group, or a cyano group. The fluorine atom may be selected in consideration of handling.

Here, Ar₁ introduced in the above Formula 3 may be phenyl, pentafluorophenyl, p-(trifluoromethyl)pentafluorophenyl, p-cyanophenyl, 2-pyrimidinyl, 5-pyrimidinyl, phthalonitrile, isophthalonitrile, pentacarbonitrile, biphenyl, 1-naphthalenyl, etc. In this case, the compounds may be used as the material for an organic EL device for forming a charge generating layer.

In addition, Ar₁ introduced in the above Formula 3 may be pentafluorophenyl, p-(trifluoromethyl)pentafluorophenyl, p-cyanophenyl, 2-pyrimidinyl, 5-pyrimidinyl, phthalonitrile, isophthalonitrile, etc. In this case, the compounds may be used as the material for an organic EL device for forming a hole injection layer.

Ar₁ in the above Formula 3 may include the following groups, for example.

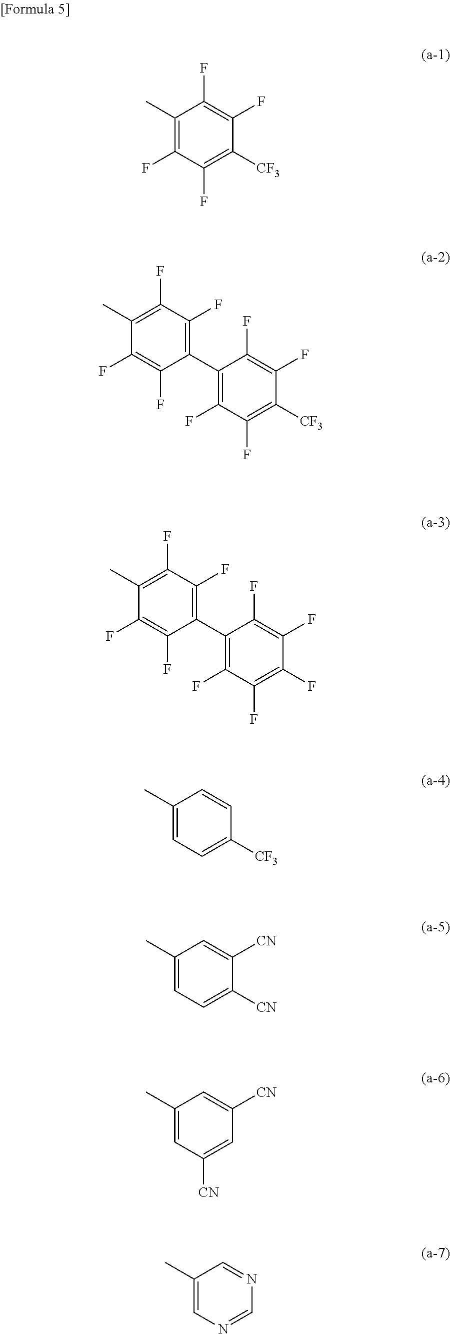

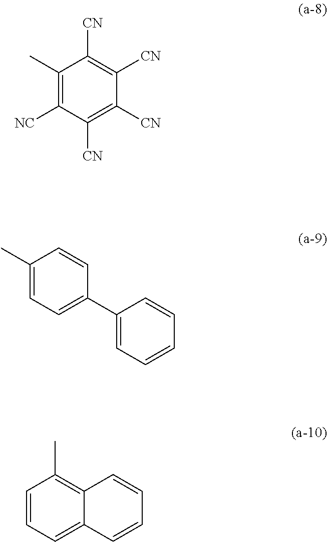

With the above-described structure, the LUMO level of a charge generating material or the LUMO level of a hole injection material may become less than or equal to about 3.40 eV, which may help realize the low voltage driving and the high power efficiency of an organic EL device.

The organic EL device according to an example embodiment includes a charge generating layer including a charge generating material or a hole injection layer including a hole injection material. The charge generating material or the hole injection material may include a compound represented by the following Formula 4, which has a structure obtained by combining two carboranes via Ar₂.

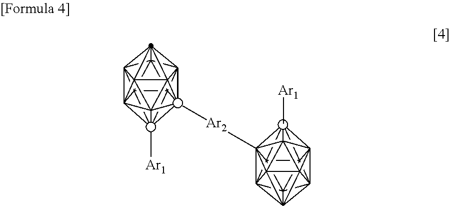

In an example embodiment, in Formula 4, Ar₁ and/or Ar₂ may be a substituted or unsubstituted aryl group or a substituted or unsubstituted heteroaryl group. For example, a substituted or unsubstituted aryl group having 6 to 12 ring carbon atoms may be used. In another example, a substituted or unsubstituted heteroaryl group having 3 to 6 ring carbon atoms may be used. The material for an organic EL device having the above-described structure may form a charge generating layer or a hole injection layer that may help realize the low voltage driving and the high power efficiency of an organic EL device.

In an example embodiment, in Formula 4, Ar₂ may be an arylene group substituted with an electroattracting group or a heteroarylene group substituted with an electroattracting group. For example, by introducing the electroattracting group in Ar₁ and/or Ar₂, the LUMO may be lowered, which may help realize the low voltage driving and the high power efficiency of an organic EL device. In another example embodiment, in Formula 4, Ar₁ may be a hydrogen atom or a deuterium atom.

The electroattracting group may be an electroattracting group having a substituent constant (σ) greater than 0.07 in the Hammett equation. By introducing the electroattracting group having a substituent constant (σ) greater than 0.07 in Ar₁ and/or Ar₂, the LUMO may be lowered, which may help realize the low voltage driving and the high power efficiency of an organic EL device.

As the electroattracting group, a halogen atom, a cyano group, or an alkyl group substituted with a halogen atom may be used. The electroattracting group may be a fluorine atom, a trifluoromethyl group, and a cyano group. The fluorine atom may be selected in consideration. Particular substituents of Ar₁ are the same as those explained referring to Formula 3, and so detailed explanation thereon will be omitted. Ar₂ may include a divalent moiety based on phenyl, 2,3,5,6-tetrafluorophenyl, 2,5-difluorophenyl, 2,5-phthalonitrile, etc.

Ar₂ in Formula 4 may include the following groups, for example.

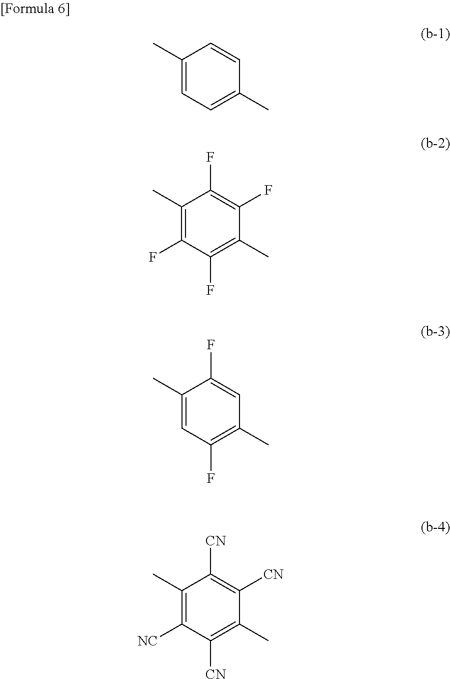

With the above-described structure, the LUMO level of a charge generating material or the LUMO level of a hole injection material may become less than or equal to about 3.40 eV, which may help realize the low voltage driving and the high power efficiency of an organic EL device.

The charge generating material according to example embodiments may include compounds represented by the following structures.

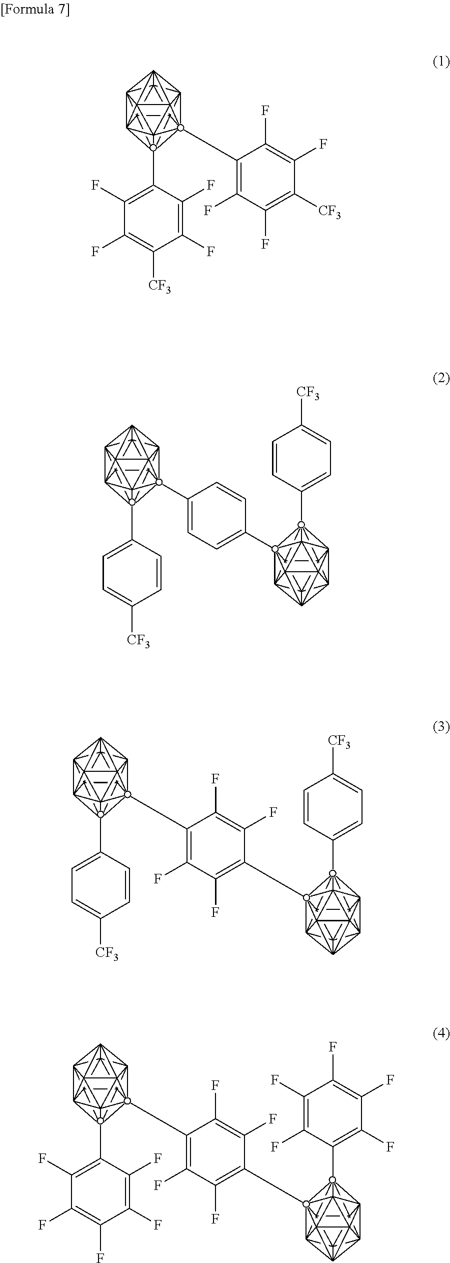

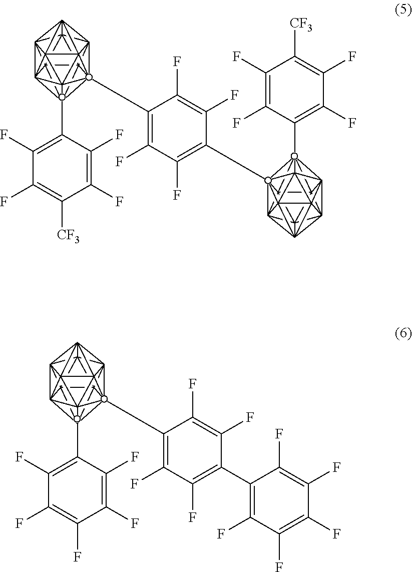

The charge generating material according to example embodiments may include compounds represented by the following structures.

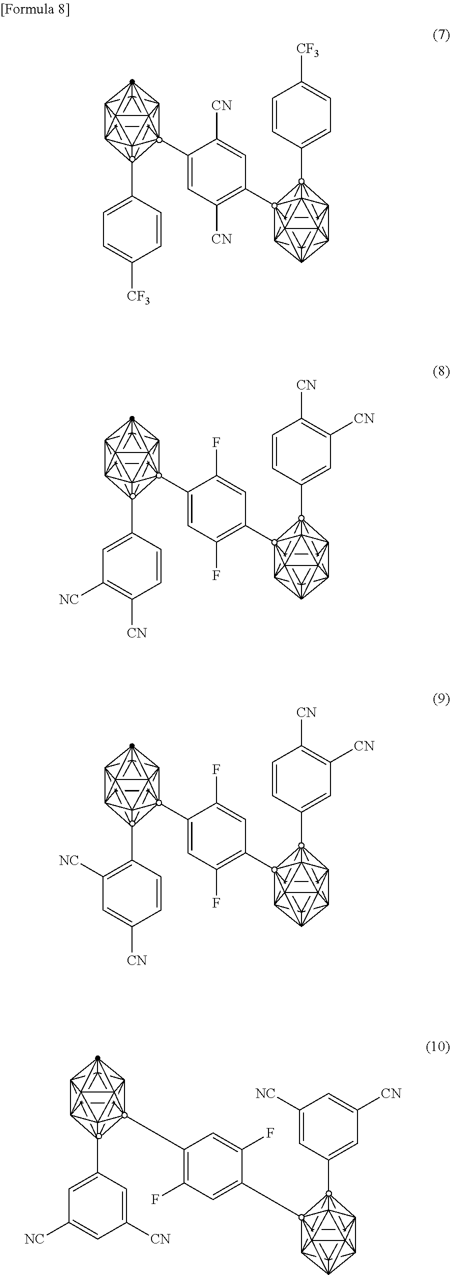

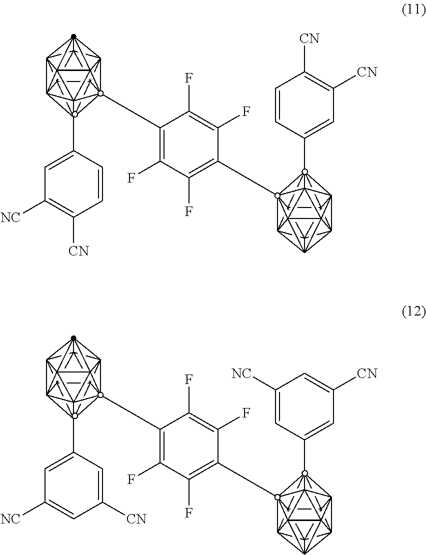

The charge generating material according to example embodiments may include compounds represented by the following structures.

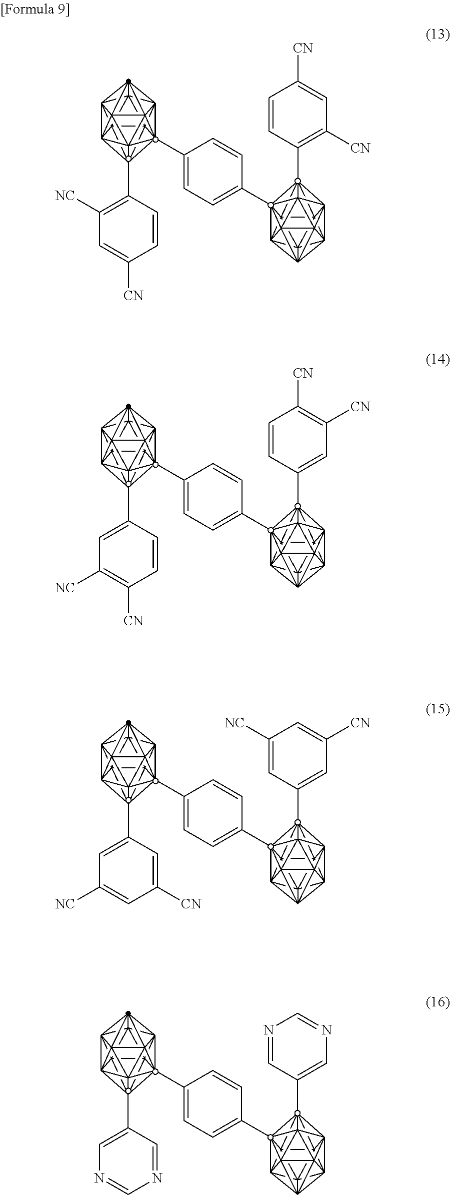

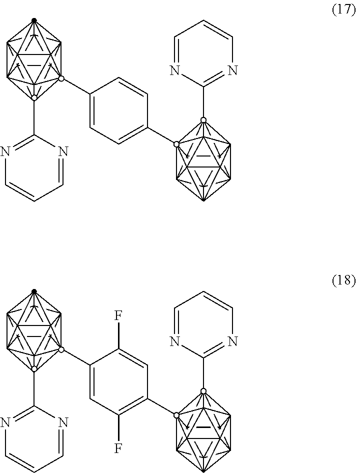

The charge generating material according to example embodiments may include compounds represented by the following structures.

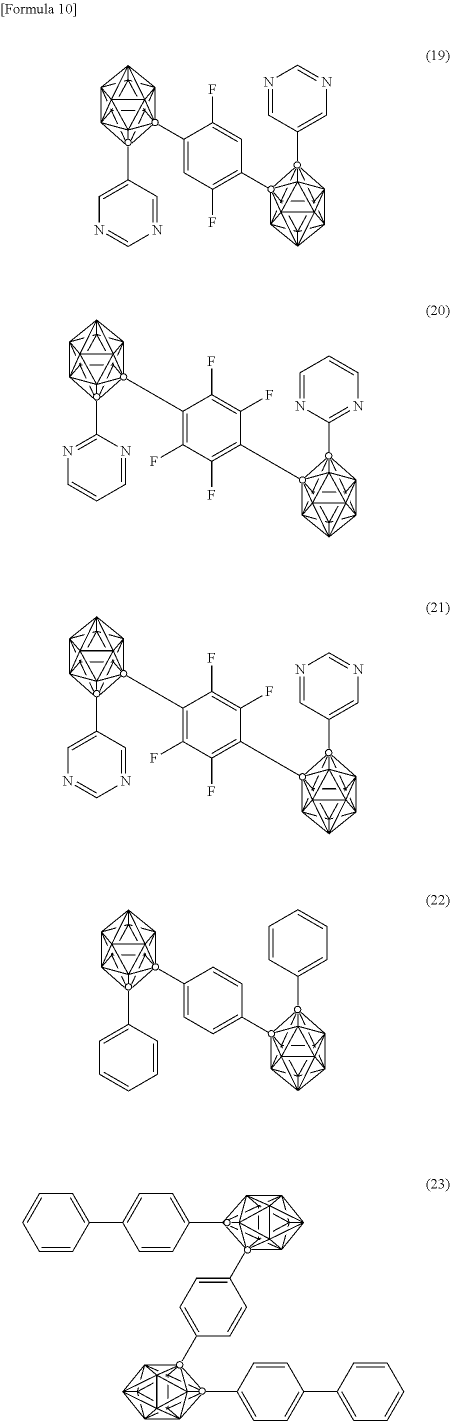

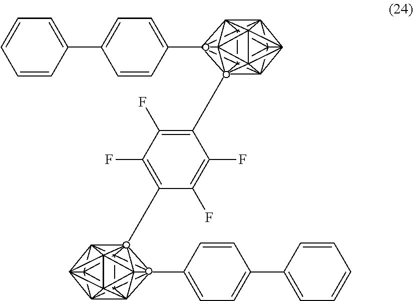

The charge generating material according to example embodiments may include compounds represented by the following structures.

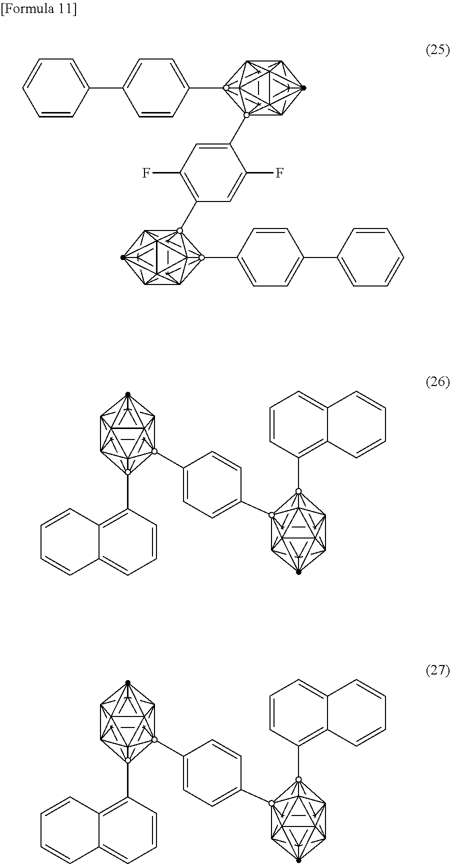

The charge generating material according to an example embodiment may be appropriately used in a charge generating layer of an organic EL device. The charge generating material according to example embodiments may provide both properties as an acceptor and a donor, and may help realize the driving of an organic EL device at a low voltage and the high power efficiency and the long life thereof.

The hole injection material according to example embodiments may include compounds represented by the following structures.

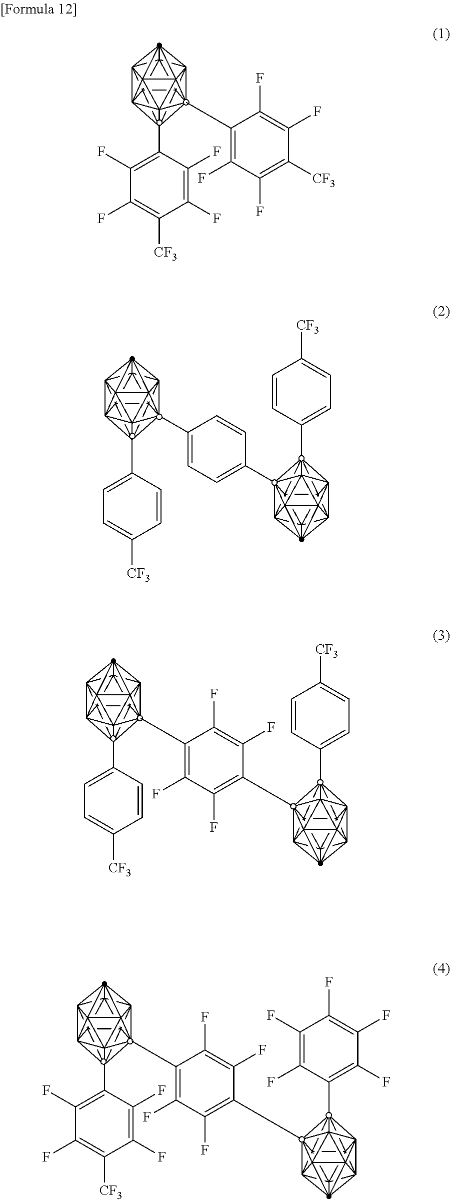

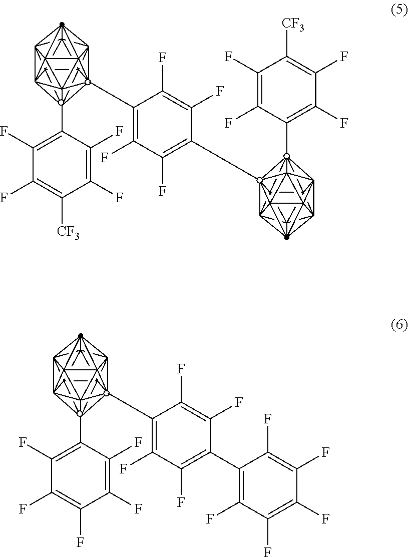

The hole injection material according to example embodiments may include compounds represented by the following structures.

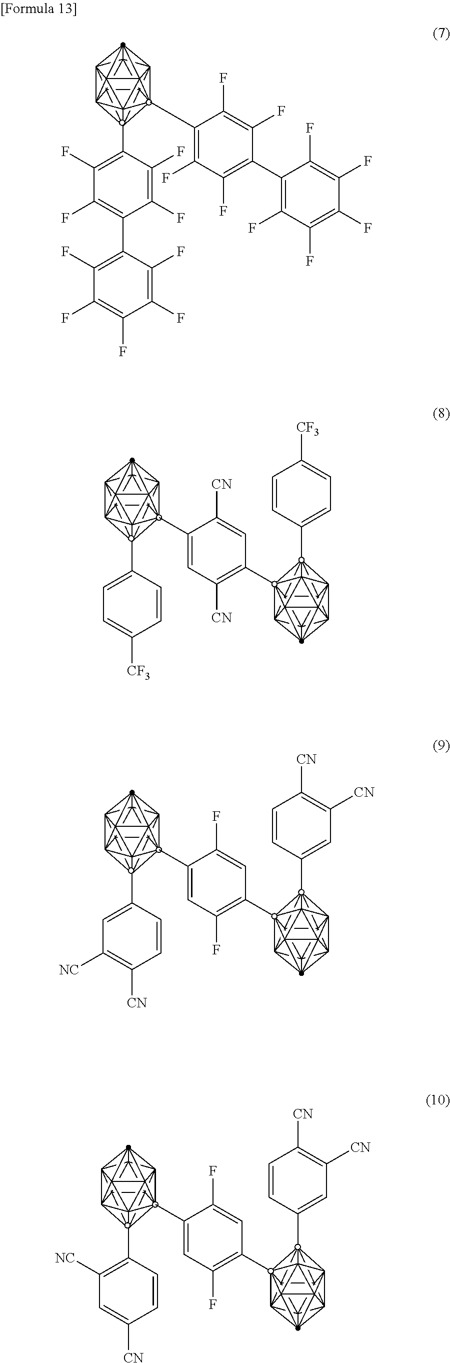

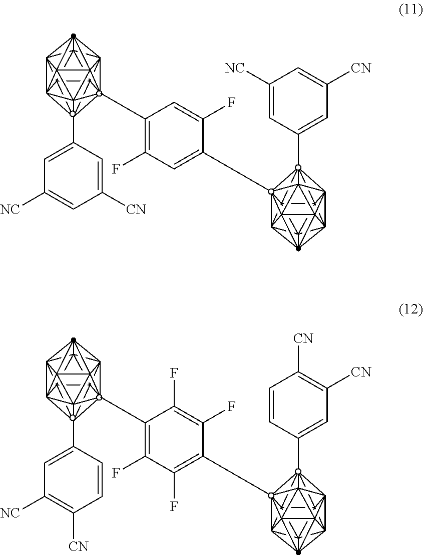

The hole injection material according to example embodiments may include compounds represented by the following structures.

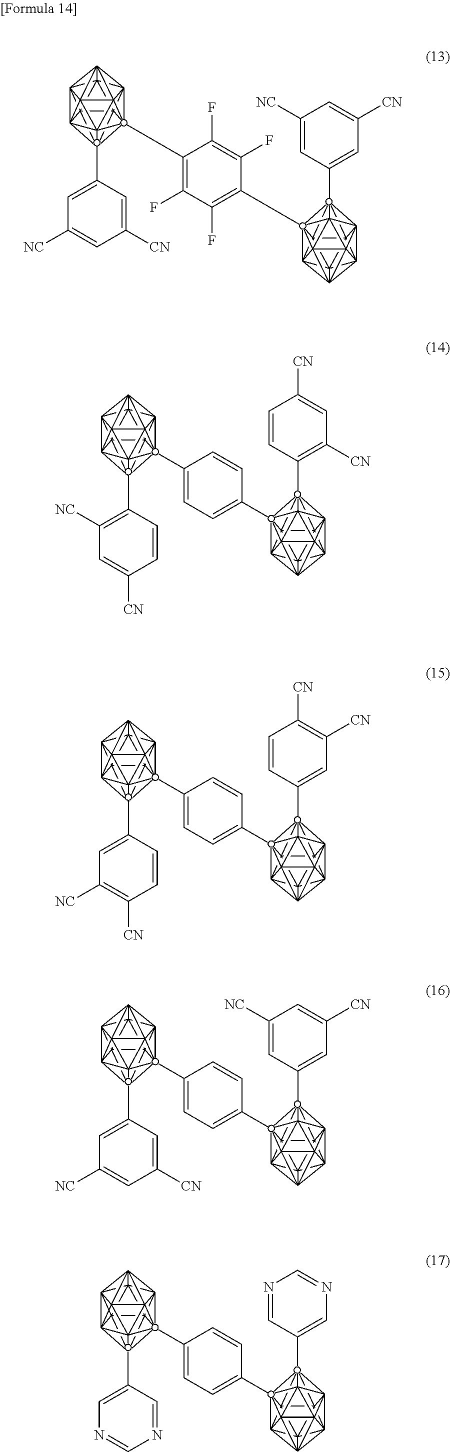

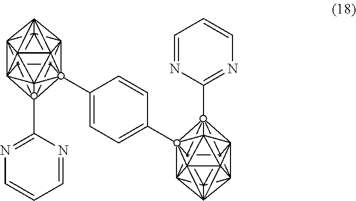

The hole injection material according to example embodiments may include compounds represented by the following structures.

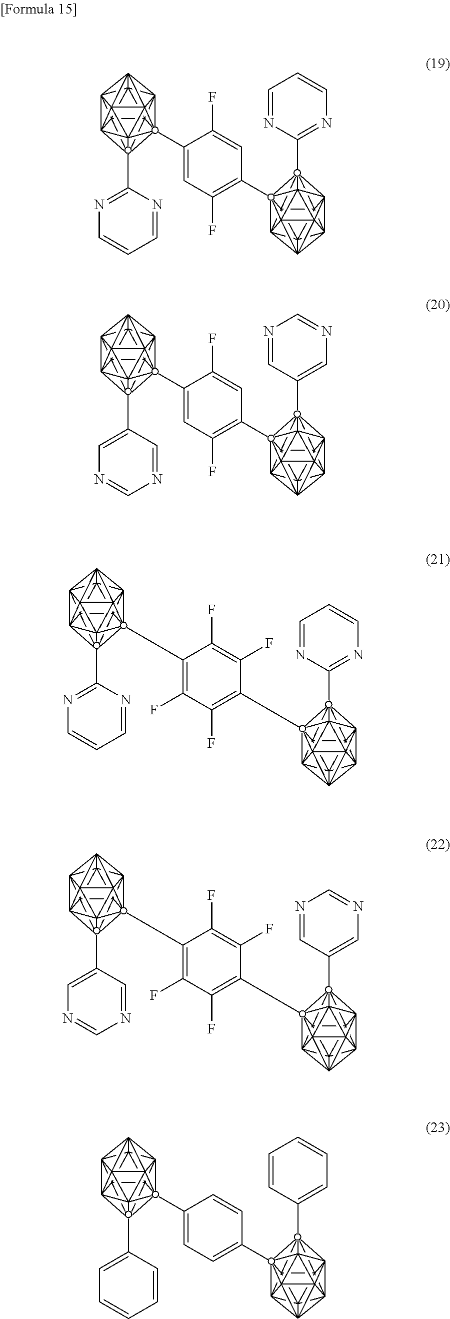

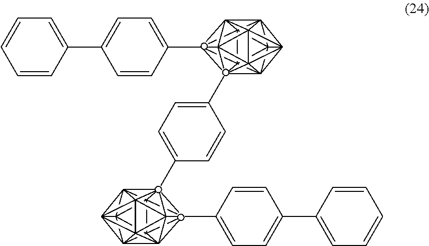

The hole injection material according to example embodiments may include compounds represented by the following structures.

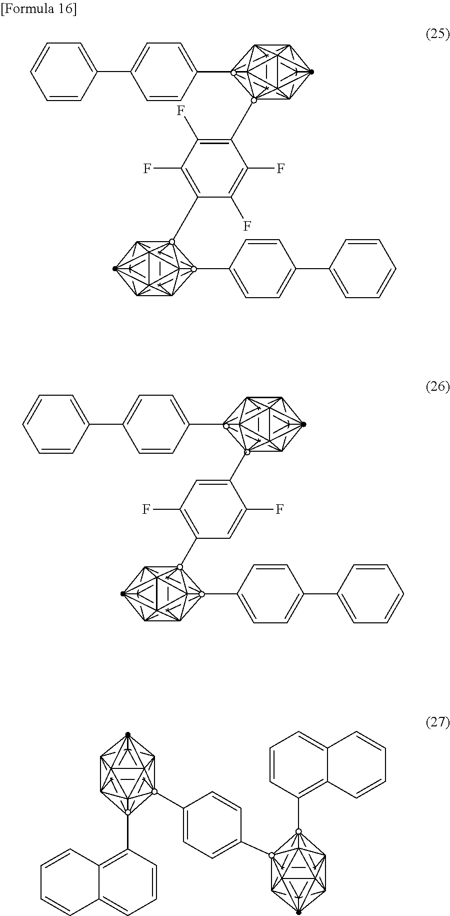

The hole injection material according to an example embodiment may be used in a hole injection layer of an organic EL device. The hole injection material according to example embodiments may provide both properties of an acceptor and a donor, and may help realize the driving of an organic EL device at a low voltage and the high power efficiency and the long life thereof.

(Organic EL Device 1)

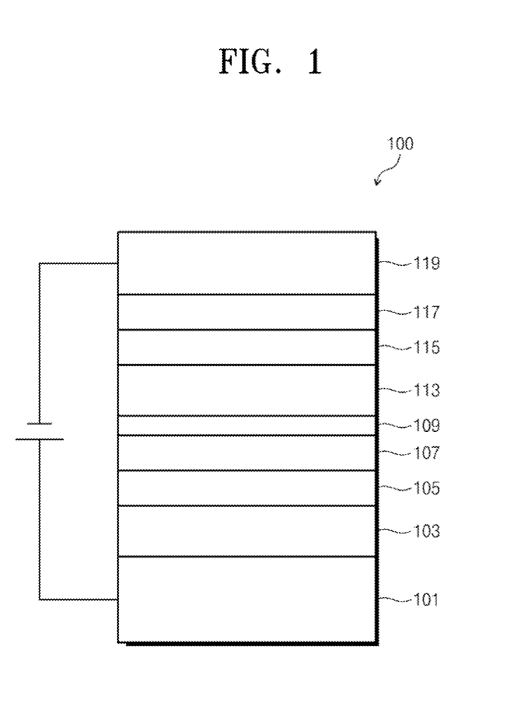

An organic EL device using the charge generating material according to example embodiments will be explained in connection with FIG. 1.

FIG. 1 illustrates a schematic diagram illustrating an organic EL device 100 according to an example embodiment.

In the organic EL device 100, for example, a first emission unit including a first hole transport layer 103, a first emission layer 105, and a first electron transport layer 107, and a second emission unit including a second hole transport layer 113, a second emission layer 115 and a second electron transport layer 117 are disposed between an anode 101 and a cathode 119 via a charge generating layer 109. In an embodiment, the charge generating material according to example embodiments may be used in a charge generating layer of an organic EL device.

In the structure in FIG. 1, two emission units are stacked with the charge generating layer 109 disposed therebetween; in other implementations, three or more emission units may be disposed with the charge generating layer 109 disposed respectively therebetween. In addition, a hole injection layer may be disposed between the anode and the hole transport layer, and an electron injection layer may be disposed between the electron transport layer and the cathode.

The anode 101 may be formed by using indium tin oxide (ITO), indium zinc oxide (IZO), etc. The hole transport layers 103 and 113 may be formed by using N,N′-di(1-naphthyl)-N,N′-diphenylbenzidine (α-NPD (NPB)), N,N′-bis(3-methylphenyl)-N,N′-diphenyl-[1,1-biphenyl]-4,4′-diamine (TPD), TACP, 4,4′-cyclohexylidene bis[N,N-bis(4-methylphenyl)benzenamine] (TAPC), triphenyl tetramer, etc. The emission layers 105 and 115 may be formed by, for example, doping tetra-t-butylperylene (TBP) in a host material including 9,10-di(2-naphthyl)anthracene (ADN). The electron transport layers 107 and 117 may be formed by using, for example, a material including tris(8-hydroxyquinolinato)aluminum (Alq3). The cathode 119 may be formed by using a metal such as Al or a transparent material such as ITO or IZO. In addition, an electron injection layer may be formed by using LiF, etc. between the electron transport layer 107 and the charge generating layer 109 and/or between the electron transport layer 117 and the cathode 119. Thin films may be formed by selecting an appropriate film forming method such as a vacuum deposition method, a sputtering method, various coating methods, etc., according to materials used.

In the organic EL device 100 according to the present example embodiment, the charge generating layer 109 may be disposed between the two emission units by using the charge generating material according to example embodiments. Forming the charge generating layer 109 using the charge generating material according to example embodiments in an MPE (multi-photon emission) type organic EL device may help realize low voltage driving and high power efficiency.

(Organic EL Device 2)

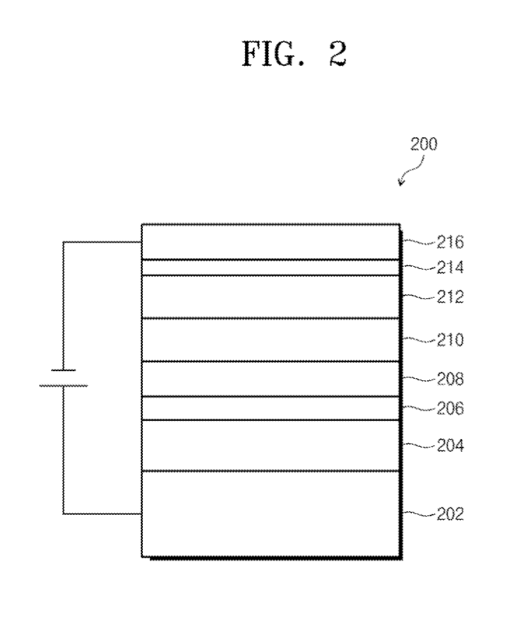

An organic EL device using the hole injection material according to an example embodiment will be explained in connection with FIG. 2.

FIG. 2 illustrates a schematic diagram illustrating an organic EL device 200 according to an example embodiment.

The organic EL device 200 includes, for example, a substrate 202, an anode 204, a hole injection layer 206, a hole transport layer 208, an emission layer 210, an electron transport layer 212, an electron injection layer 214 and a cathode 216. According to an embodiment, the hole injection material according to example embodiments may be used in a hole injection layer of an organic EL device.

The substrate 202 may be, for example, a transparent glass substrate or a flexible substrate such as a semiconductor substrate composed of silicon, etc, or a resin, etc. The anode 204 may be disposed on the substrate 202 and may be formed by using ITO, IZO, etc. The hole injection layer 206 may be disposed on the anode 204 and may be formed by using the hole injection material according to example embodiments. The hole transport layer 208 may be disposed on the hole injection layer 206 and may be formed by using α-NPD(NPB), TPD, TACP, TAPC, triphenyl tetramer, etc. The emission layer 210 may be disposed on the hole transport layer 208 and may be formed, for example, by doping TBP in a host material including ADN, etc. The electron transport layer 212 may be disposed on the emission layer 210 and may be formed by using, for example, a material including Alq3. The electron injection layer 214 may be disposed on the electron transport layer 212 and may be formed by using a material including lithium fluoride (LiF). The cathode 216 may be disposed on the electron injection layer 214 and may be formed by using a transparent material by using a metal such as Al or a transparent material such as ITO, IZO, etc. Thin films may be formed by selecting an appropriate film forming method such as a vacuum deposition method, a sputtering method, various coating methods, etc. according to materials used.

Using the hole injection material according to example embodiments in the organic EL device 200 according to this embodiment in a hole injection layer may help realized low voltage driving and high power efficiency. In addition, the hole injection material according to example embodiments may be applied in an organic EL device of an active matrix using thin film transistor (TFT).

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Examples

### Preparation Method 1

A charge generating material according to an example embodiment may be prepared, for example, using the following method.

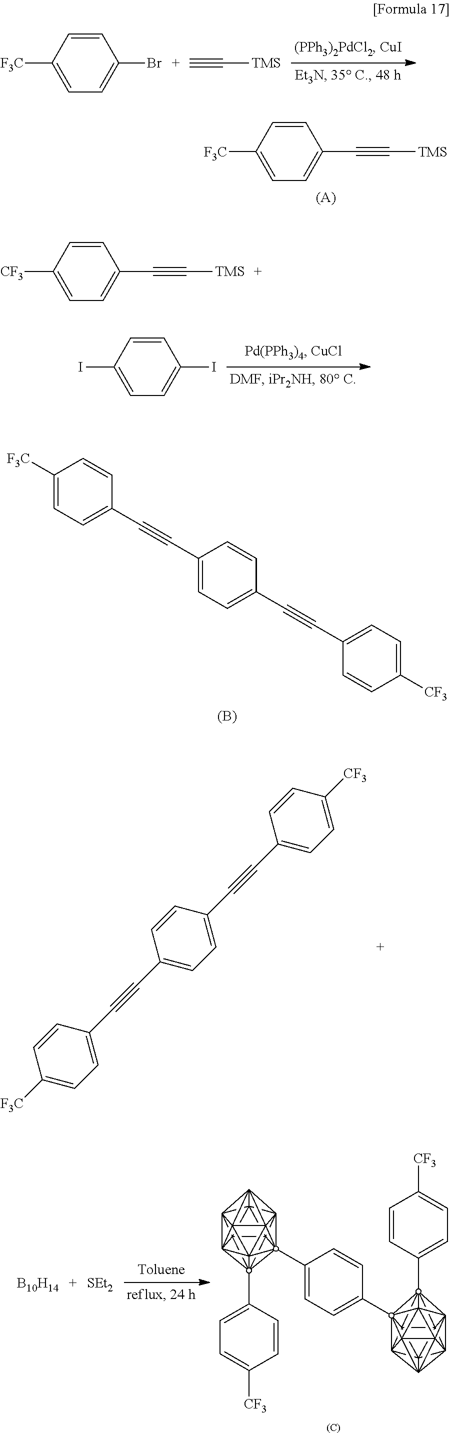

Synthesis of Compound (A)

To a reaction system of a mixture of 4-bromobenzotrifluoride (5.3 g, 18 mmol), CuI (50 mg, 0.26 mmol), PdCl₂(PPh₃)₂ (200 mg, 0.28 mmol), and 20 ml of Et₃N, trimethylsilylacetylene (2 g, 20 mmol) was added, followed by stirring under an N₂ gas atmosphere at 35° C. for 48 hours. After completing the reaction, the reaction product was separated by means of chromatography to obtain 4.3 g of Compound (A) (yield 91%).

Synthesis of Compound (B)

Compound (A) (5.6 g, 23 mmol), diethyl sulfide (3.3 g, 10 mmol), and CuCl (2.1 g, 21 mmol) were added in 45 ml of a mixture solvent of N₂-purged DMF:i-Pr₂NH=2:1. Finally, Pd(PPh₃)₄ (1.2 g, 1 mmol) was added thereto and stirred under an N₂ gas atmosphere at 80° C. overnight. After completing the reaction, the reaction product was separated by performing filtration on SiO₂ phase, extraction with Et₂O and chromatography to obtain 1.9 g of Compound (B) (yield 46%).

Identification of Compound (B)

The chemical shift values of Compound (B) measured by ¹H-NMR (400 MHz, CDCl₃) were δ7.52 (d, 4H) and δ7.60 (m, 8H). In addition, the chemical shift value of Compound (B) measured by ¹⁹F-NMR was δ—62.44 (s, 6F, —CF₃). The molecular weight of Compound (B) measured by HRMS was 414.0843, and Compound (B) was identified as C₂₄H₁₂F₆ (414.0843).

Synthesis of Compound (2)

Decaborane (269 mg, 2.2 mmol) and diethyl sulfide (497 μl, 4.6 mmol) were refluxed for 4.5 hours. Then, toluene (10 ml) and Compound (B) (414 mg, 1 mmol) were added thereto, followed by refluxing for 24 hours. Reaction solvents were concentrated and the reaction product was separated by means of chromatography using petroleum ether to obtain 240 mg of Compound (2) (yield 37%).

Identification of Compound (2)

The chemical shift values of Compound (2) measured by ¹H-NMR (400 MHz, CDCl₃) were δ7.19 (s, 4H) and δ7.37 (dd, 8H). In addition, the chemical shift value of Compound (2) measured by ¹⁹F-NMR was δ—63.03 (s, 6F, —CF₃). The molecular weight of Compound (2) measured by FIRMS was 650.4414, and Compound (2) was identified as C₂₄H₃₂B₂OF₆ (650.4415).

According to the preparation method described above, Compounds (1) to (5) according to Examples 1 to 5 were prepared. In addition, 1,4,5,8,9,12-hexaazatriphenylenehexacarbonitrile (HAT(CN)₆) was prepared as Comparative Example 1.

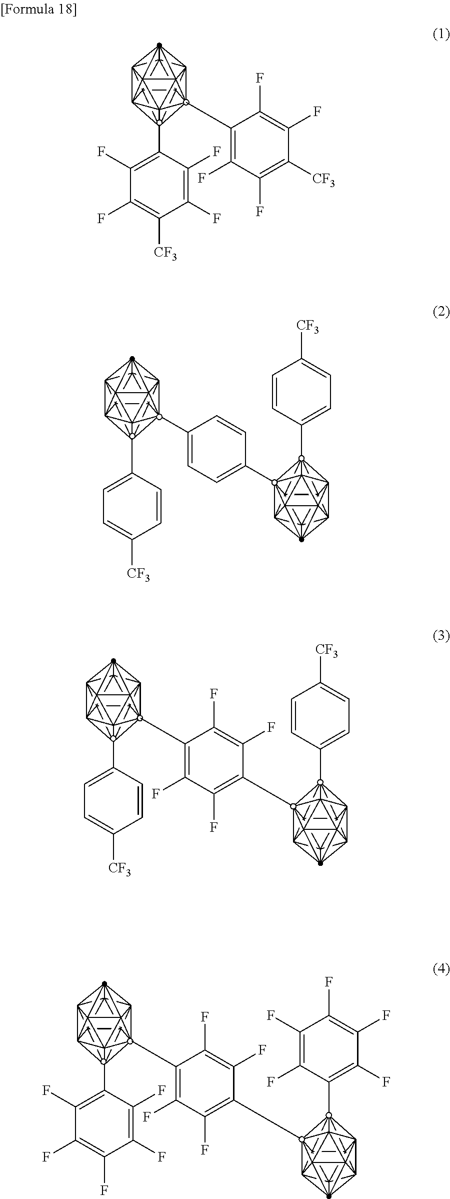

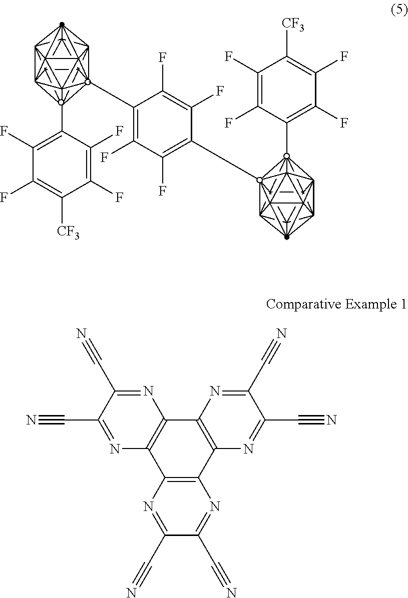

Organic EL devices were manufactured by using Compounds (1) to (5) according to Examples 1 to 5 and the compound of Comparative Example 1 as charge generating materials.

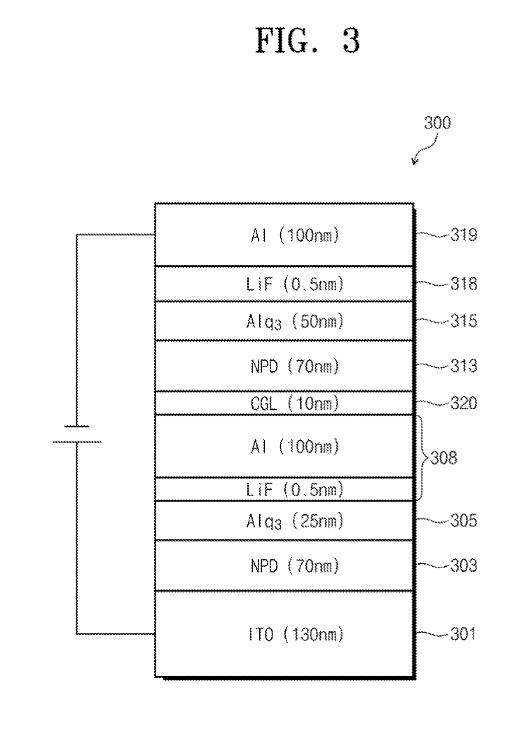

FIG. 3 illustrates a schematic diagram illustrating an organic EL device 300 according to Examples 1 to 5.

Referring to FIG. 3, an anode 301 was formed using ITO to a thickness of about 130 nm, a first hole transport layer 303 was formed using NPD to a thickness of about 70 nm, a first emission layer and an electron transport layer 305 were formed using Alq3 to a thickness of about 50 nm, a first electron injection layer 308 was formed using LiF to a thickness of about 0.5 nm and Al to a thickness of about 100 nm, and a charge generating layer 320 was formed using the charge generating materials according to Examples 1 to 5 and Comparative Example 1 to a thickness of about 70 nm. Then, a second hole transport layer 313 was formed using NPD to a thickness of about 70 nm, a second emission layer and an electron transport layer 315 were formed using Alq3 to a thickness of about 50 nm, a second electron injection layer 318 was formed using LiF to a thickness of about 0.5 nm, and a cathode 319 was formed using Al to a thickness of about 100 nm.

With respect to the organic EL devices, the voltage and the power efficiency was evaluated when current density was 10 mA/cm². The evaluation results are illustrated in the following Table 1.

TABLE 1

| | Voltage | Power efficiency |
|---|---|---|
| | (V) | (lm/w) |
| Example 1 | 7.50 | 2.94 |
| Example 2 | 8.1 | 2.62 |
| Example 3 | 7.93 | 2.67 |
| Example 4 | 7.49 | 2.82 |
| Example 5 | 7.04 | 2.82 |
| Comparative | 8.81 | 2.4 |
| Example 1 | | |

Current density: 10 mA/cm²

As clearly shown in Table 1, the organic EL devices using the compounds according to Examples 1 to 5 had equal or better properties when compared to the organic EL device using the compound of Comparative Example 1, and were capable of being driven at a low voltage and had high power efficiency as well as high current efficiency. Without being bound by theory, the results are assumed to be obtained by using a charge generating material obtained by introducing an aromatic substituent having an electroattracting group in carborane having high stability, which is a material having acceptor properties.

### Preparation Method 2

A hole injection material according to an example embodiment may be prepared, for example, using the following method.

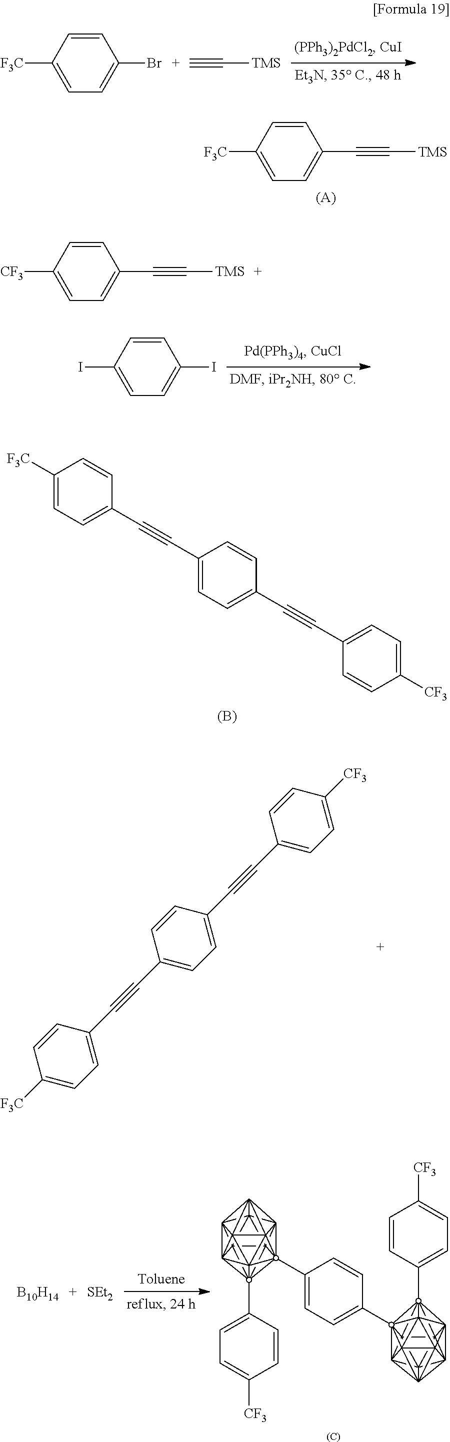

Synthesis of Compound (A)

To a reaction system of a mixture of 4-bromobenzotrifluoride (5.3 g, 18 mmol), CuI (50 mg, 0.26 mmol), PdCl₂(PPh₃)₂ (200 mg, 0.28 mmol), and 20 ml of Et₃N, trimethylsililacetylene (2 g, 20 mmol) was added, followed by stirring under an N₂ gas atmosphere at 35° C. for 48 hours. After completing the reaction, the reaction product was separated by means of chromatography to obtain 4.3 g of Compound (A) (yield 91%).

Synthesis of Compound (B)

Compound (A) (5.6 g, 23 mmol), diethyl sulfide (3.3 g, 10 mmol), and CuCl (2.1 g, 21 mmol) were added in a mixture solvent of N₂-substituted DMF:i-Pr₂NH=2:1. Finally, Pd(PPh₃)₄ (1.2 g, 1 mmol) was added and stirred under an N₂ gas atmosphere at 80° C. overnight. After completing the reaction, the reaction product was separated by performing filtration on SiO₂ phase, extraction with Et₂O and chromatography to obtain 1.9 g of Compound (B) (yield 46%).

Identification of Compound (B)

The chemical shift values of Compound (B) measured by ¹H-NMR (400 MHz, CDCl₃) were δ7.52 (d, 4H) and δ7.60 (m, 8H). In addition, the chemical shift value of Compound (B) measured by ¹⁹F-NMR was δ—62.44 (s, 6F, —CF₃). The molecular weight of Compound (B) measured by HRMS was 414.0843, and Compound (B) was identified as C₂₄H₁₂F₆ (414.0843).

Synthesis of Compound (7)

Decaborane (269 mg, 2.2 mmol) and diethyl sulfide (497 μl, 4.6 mmol) were refluxed for 4.5 hours. Then, toluene (10 ml) and Compound (B) (414 mg, 1 mmol) were added thereto, followed by refluxing for 24 hours. Reaction solvents were concentrated and the reaction product was separated by means of chromatography using petroleum ether to obtain 240 mg of Compound (7) (yield 37%).

Identification of Compound (7)

The chemical shift values of Compound (7) measured by ¹H-NMR (400 MHz, CDCl₃) were δ7.19 (s, 4H) and δ7.37 (dd, 8H). In addition, the chemical shift value of Compound (7) measured by ¹⁹F-NMR was δ—63.03 (s, 6F, —CF₃). The molecular weight of Compound (7) measured by HRMS was 650.4414, and Compound (7) was identified as C₂₄H₃₂B₂OF₆ (650.4415).

According to the preparation method described above, Compounds (6) to (10) according to Examples 6 to 10 were prepared. In addition, 1,4,5,8,9,12-hexaazatriphenylenehexacarbonitrile (HAT(CN)₆) was prepared as Comparative Example 2.

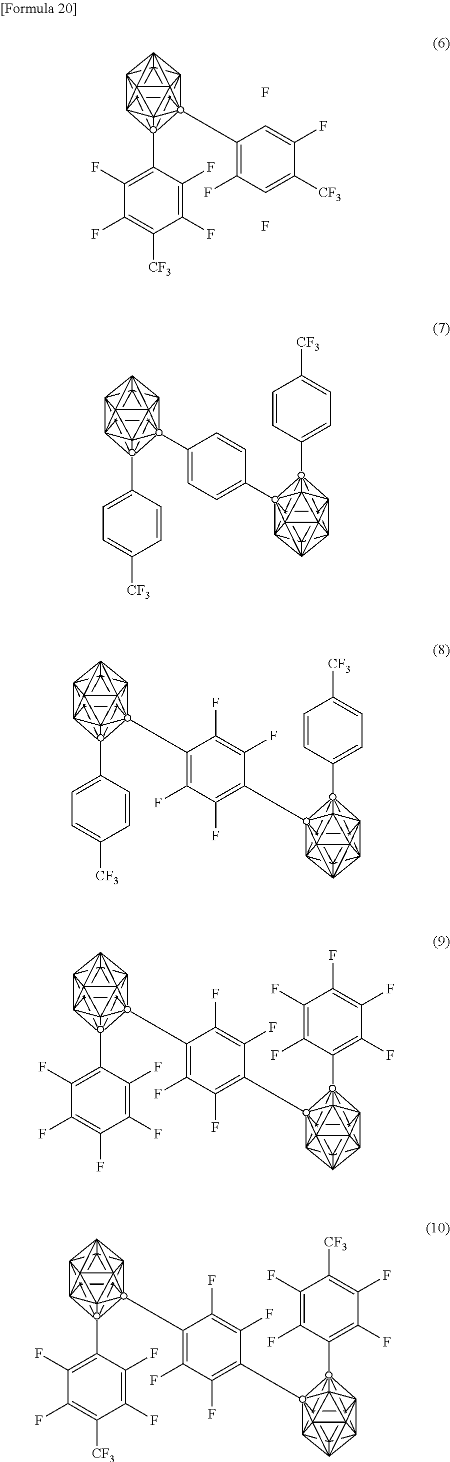

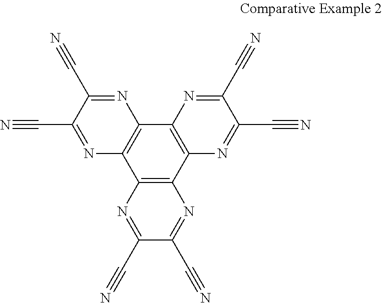 [SMILES: N#Cc1nc2c3nc(C#N)c(C#N)nc3c3nc(C#N)c(C#N)nc3c2nc1C#N]

Organic EL devices were manufactured by using Compounds (6) to (10) according to Examples 6 to 10 and the compound of Comparative Example 2 as hole injection materials.

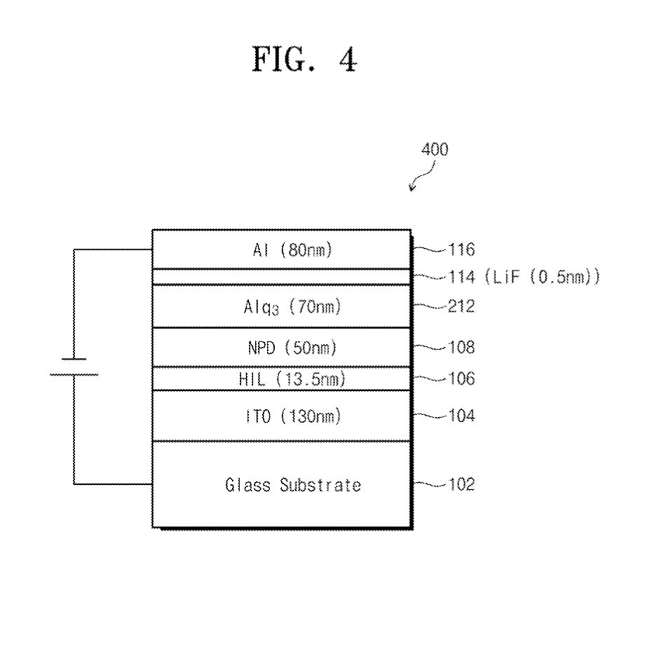

FIG. 4 illustrates a schematic diagram illustrating an organic EL device 400 according to Examples 6 to 10.

Referring to FIG. 4, a substrate 402 was formed by using a transparent glass substrate, and an anode 404 was formed using ITO to a thickness of about 130 nm, a hole injection layer 406 was formed to a thickness of about 13.5 nm using the hole injection materials according to Examples 6 to 10 and Comparative Example 2, a hole transport layer 408 was formed using NPD to a thickness of about 50 nm, an emission layer and an electron transport layer 412 were formed using Alq3 to a thickness of about 70 nm, an electron injection layer 414 was formed using LiF to a thickness of about 0.5 nm and a cathode 416 was formed using Al to a thickness of about 80 nm. In Comparative Example 2, an organic EL device was manufactured by the same procedure applied in the examples except for forming a hole injection layer 406 to a thickness of about 5 nm, a hole transport layer 408 using NPD to a thickness of about 45 nm, and an electron transport layer 412 using Alq3 to a thickness of about 90 nm.

With respect to the organic EL devices, the voltage and the power efficiency was evaluated when current density was 10 mA/cm². The evaluation results are illustrated in the following Table 2.

TABLE 2

| | Voltage | Power efficiency |
|---|---|---|
| | (V) | (lm/w) |
| Example 6 | 4.1 | 3.0 |
| Example 7 | 3.4 | 2.5 |
| Example 8 | 3.6 | 2.6 |
| Example 9 | 3.8 | 3.0 |
| Example 10 | 4.2 | 3.1 |
| Comparative | 4.4 | 2.4 |
| Example 2 | | |

Current density: 10 mA/cm²

As clearly shown in Table 2, the organic EL devices using the compounds according to Examples 6 to 10 had low LUMO levels and high power efficiency when compared to the organic EL device using the compound of Comparative Example 2. Without being bound by theory, it is believed that the results are assumed to be obtained by using a hole injection material obtained by introducing an aromatic substituent having an electroattracting group in carborane having high stability, which is a material having acceptor properties.

By way of summation and review, carborane is a cluster molecule composed on a boron atom and a carbon atom. The carborane follows Huckel's rule, exhibits super-aromatic nature, and has high thermodynamic stability. In addition, carborane has a polyhedron structure, is appropriate as a material having electron accepting properties, and is available in a charge generating layer or a hole injection layer of an organic EL device.

An example of an organic electroluminescence device (hereinafter referred to as an organic EL device) is an organic EL device that includes an anode, a hole transport layer disposed on the anode, an emission layer disposed on the hole transport layer, an electron transport layer disposed on the emission layer, and a cathode disposed on the electron transport layer. Holes injected from the anode are injected into the emission layer via the hole transport layer. Meanwhile, electrons are injected from the cathode, and then injected into the emission layer via the electron transport layer. The holes and the electrons injected into the emission layer are recombined to generate excitons within the emission layer. The organic EL device emits light by using light generated by the radiation and deactivation of the excitons. The configuration of the organic EL device may be changed in various forms.

A device structure referred to as multi-photon emission (MPE), in which plural emission units including at least a hole transport layer, an emission layer, and a charge transport layer are stacked in series, may provide enhanced emission efficiency and life. A charge generating layer generating each of holes and electrons is disposed in a stack between at least two emission units between an anode and a cathode. In applying an MPE type organic EL device in a display device, high efficiency and long life are desired. Increase of the efficiency and the life of a charge generating layer life is a consideration. In addition, to help realize an organic device having high efficiency and long life, normalization, stabilization, and durability increase of a hole injection layer are a consideration.

As described above, according to an embodiment, an organic EL device realizing low voltage driving and high power efficiency and a material for an organic EL device may be provided. Embodiments relate to an organic electroluminescence device for an organic electroluminescence device having high efficiency and long life and a material for an organic electroluminescence device. A charge generating layer that may help realize the driving at a low voltage of an organic EL device with high power efficiency may be formed by introducing a 1,2-closo-carborane compound combined with an aryl group or a heteroaryl group at carbons of position 1 and position 2. A hole injection layer that may help realize the driving at a low voltage of an organic EL device with high power efficiency may be formed by introducing a 1,2-closo-carborane compound combined with an aryl group or a heteroaryl group at carbons of position 1 and position 2.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic electroluminescence (EL) device comprising a charge generating layer including a charge generating material or a hole injection layer including a hole injection material,
the charge generating material or the hole injection material including a 1,2-closo-carborane compound represented by the following Formula 1: 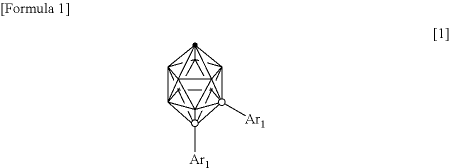
wherein each Arₜ is independently a substituted or unsubstituted aryl group or a substituted or unsubstituted heteroaryl group.

2. The organic EL device as claimed in claim 1, wherein each Ar₁ is independently an aryl group substituted with an electroattracting group or a heteroaryl group substituted with an electroattracting group.

3. The organic EL device as claimed in claim 2, wherein the electroattracting group is an electroattracting group having a substituent constant (r) greater than 0.07 in the Hammett equation.

4. The organic EL device as claimed in claim 2, wherein the electroattracting group is a halogen atom, a methyl group substituted with a halogen atom, or a cyano group.

5. The organic EL device as claimed in claim 1, wherein a lowest unoccupied molecular orbital (LUMO) level of the charge generating material or a LUMO level of the hole injection material is less than or equal to about 3.40 eV.

6. The organic EL device as claimed in claim 1, wherein:
the organic EL device includes the charge generating layer, and
the organic EL device includes at least a first emission unit and a second emission unit, the first and second emission units being stacked in series, the stacked emission units including, in sequence, an anode, a first emission layer, the charge generating layer, a second emission layer, and a cathode.

7. An organic electroluminescence (EL) device comprising a charge generating layer including a charge generating material or a hole injection layer including a hole injection material,
the charge generating material or the hole injection material including a 1,2-closo-carborane compound represented by the following Formula 2: 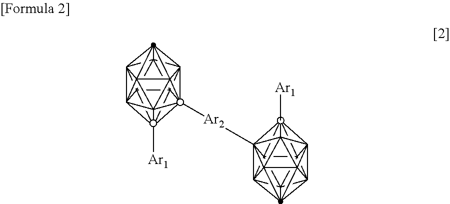
wherein each Ar₁ and Ar₂ are independently a substituted or unsubstituted aryl group or a substituted or unsubstituted heteroaryl group.

8. The organic EL device as claimed in claim 7, wherein at least one of Ar₁ or Ar₂ is an aryl group substituted with an electroattracting group or a heteroaryl group substituted with an electroattracting group.

9. The organic EL device as claimed in claim 8, wherein the electroattracting group is an electroattracting group having a substituent constant (a) greater than 0.07 in the Hammett equation.

10. The organic EL device as claimed in claim 8, wherein the electroattracting group is a halogen atom, a methyl group substituted with a halogen atom, or a cyano group.

11. The organic EL device as claimed in claim 7, wherein a lowest unoccupied molecular orbital (LUMO) level of the charge generating material or a LUMO level of the hole injection material is less than or equal to about 3.40 eV.

12. The organic EL device as claimed in claim 7, wherein:
the organic EL device includes the charge generating layer, and
the organic EL device includes at least a first emission unit and a second emission unit, the first and second emission units being stacked in series, the stacked emission units including, in sequence, an anode, a first emission layer, the charge generating layer, a second emission layer, and a cathode.

13. A material for an organic electroluminescence (EL) device comprising a 1,2-closo-carborane compound represented by the following Formula 1: 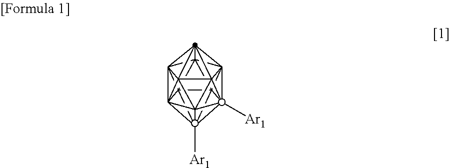
wherein each Ar₁ is independently an aryl group substituted with an electroattracting group or a heteroaryl group substituted with an electroattracting group.

14. The material for an organic EL device as claimed in claim 13, wherein the electroattracting group is an electroattracting group having a substituent constant (σ) greater than 0.07 in the Hammett equation.

15. The material for an organic EL device as claimed in claim 13, wherein the electroattracting group is a halogen atom, a methyl group substituted with a halogen atom, or a cyano group.

16. The organic EL device as claimed in claim 13, wherein a lowest unoccupied molecular orbital (LUMO) level of the material is less than or equal to about 3.40 eV.

17. A material for an organic electroluminescence (EL) device comprising a 1,2-closo-carborane compound represented by the following Formula 2: 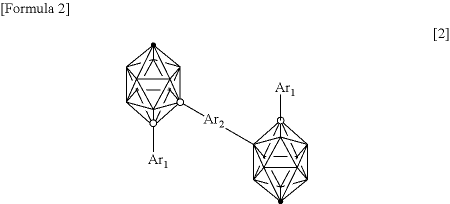
wherein each Ar₁ and Ar₂ are independently a substituted or unsubstituted aryl group or a substituted or unsubstituted heteroaryl group.

18. The material for an organic EL device as claimed in claim 17, wherein at least one of Ar₁ or Ar₂ is an aryl group substituted with an electroattracting group or a heteroaryl group substituted with an electroattracting group.

19. The material for an organic EL device as claimed in claim 18, wherein the electroattracting group is an electroattracting group having a substituent constant (a) greater than 0.07 in the Hammett equation.

20. The material for an organic EL device as claimed in claim 18, wherein the electroattracting group is a halogen atom, a methyl group substituted with a halogen atom, or a cyano group.

21. The organic EL device as claimed in claim 17, wherein a lowest unoccupied molecular orbital (LUMO) level of the material is less than or equal to about 3.40 eV.
